(19) United States
(12) Patent Application Publication
(10) Pub. No.: US 2023/0037481 A1
(43) Pub. Date: Feb. 9, 2023

(54) Dual-conductive key switch

(71) Applicants: Dongguan City Kaihua Electronics Co., Ltd, Dongguan (CN); MECHANICAL KEYBOARDS, LLC., CHANDLER, AZ (US)

(72) Inventors: Joel Tubre, Phoenix, AZ (US); FuXi Wu, Dongguan (CN)

(73) Assignee: MECHANICAL KEYBOARDS, LLC., CHANDLER, AZ (US)

(21) Appl. No.: 17/397,943

(22) Filed: Aug. 9, 2021

(51) Int. Cl. H01H 13/14; H01H 13/04; H01H 13/64; H01H 13/50; G01R 33/07

(52) U.S. Cl. CPC H01H 13/14; H01H 13/04; H01H 13/64; H01H 13/503; G01R 33/07

(57) ABSTRACT

The utility model discloses a dual-conductive key switch comprising a base, a cover arranged above the base, and a conductive core, wherein it further comprises a first conducting component and a second conducting component which are triggered to conduct sequentially by the conductive core. According to the utility model, the dual-conductive key switch is provided for achieving dual-conductive function of pressing once and performing two actions for a product, which gives more functions to the key switch and provides better user experience.

### TECHNICAL FIELD

The utility model relates to the field of keyboard switches, in particular to a dual-conductive key switch.

### BACKGROUND ART

At present, when a key switch on the market is pressed once, the key switch is only conductive once, that is, the key switch only has a single conduction function. Along with the wide application of the key switch, not only the key switch is continuously improved for its performance requirement, but also the function requirement to the key switch is higher and higher.

For example, it is required that the key switch can be conductive twice when the key switch is pressed once. When it is applied to games, the key switch with the function of being pressed once and conductive twice has higher speed and provides better user experience for players compared with the traditional key switch.

However, the key switches with the function of being pressed once and conductive twice have not been available on the market today.

### SUMMARY OF THE UTILITY MODEL

For the defects above, the purpose of the utility model is to provide a dual-conductive key switch for achieving dual-conductive function of pressing once and performing two actions for a product, which gives more functions to the key switch and provides better user experience.

The technical solution adopted by the utility model for achieving the above purpose is as follows.

A dual-conductive key switch comprises a base, a cover arranged above the base, and a conductive core, wherein it further comprises a first conducting component and a second conducting component which are triggered to conduct sequentially by the conductive core.

As a further improvement of the utility model, at least one first conducting trigger corresponding to the first conducting component and at least one second conducting trigger corresponding to the second conducting component are respectively arranged on the conductive core; and the first conducting trigger triggers a conduction stroke of conducting the first conducting component, which is different from a conduction stroke of conducting the second conducting component triggered by the second conducting trigger.

As a further improvement of the utility model, a first inclined surface is formed on the side edge of the first conducting trigger, a second inclined surface is formed on the side edge of the second conducting trigger, and the slope of the first inclined surface is greater than that of the second inclined surface edgez

As a further improvement of the utility model, the first conducting component comprises a first stationary plate and a first movable plate, a first stationary contact is arranged on the first stationary plate, a first movable contact corresponding to the first stationary contact is arranged on the first movable plate, and at least one first contact protrusion corresponding to the first conducting trigger is formed on the first movable plate; and the second conducting component comprises a second stationary plate and a second movable plate, a second stationary contact is arranged on the second stationary plate, a second movable contact corresponding to the second stationary contact is arranged on the second movable plate, and at least one second contact protrusion corresponding to the second conducting trigger is formed on the second movable plate.

As a further improvement of the utility model, the first conducting component is a light-conducting component A electrically connected to a PCB, and the second conducting component is a light-conducting component B electrically connected to the PCB; the first conducting trigger is a light-blocking protrusion A, and the second conducting trigger is a light-blocking protrusion B, and the distance between the light-blocking protrusion A and the light-conducting component A is less than the distance between the light-blocking protrusion B and the light-conducting component B.

As a further improvement of the present utility model, the height of the light-blocking protrusion A is the same as that of the light-blocking protrusion B, and the height of the light-conducting component A is higher than that of the light-conducting component B.

As a further improvement of the present utility model, the height of the light-blocking protrusion A is lower than that of the light-blocking protrusion B, and the height of the light-conducting component A is the same as that of the light-conducting component B.

As a further improvement of the utility model, a first abdicating opening for the light-blocking protrusion A and the light-blocking protrusion B respectively to move up and down is formed on the base.

As a further improvement of the present utility model, the light-conducting component A and the light-conducting component B have a same structure and comprises a light emission element and a light reception element.

As a further improvement of the utility model, the first conducting component is an inductive switch A electrically connected to the PCB, and the second conducting component is an inductive switch B electrically connected to the PCB; the first conducting trigger is a magnet A, and the second conducting trigger is a magnet B; and the distance between the magnet A and the inductive switch A is less than the distance between the magnet B and the inductive switch B.

As a further improvement of the utility model, the height of the magnet A is the same as that of the magnet B, and the height of the inductive switch A is higher than that of the inductive switch B.

As a further improvement of the utility model, the height of the magnet A is lower than that of the magnet B, and the height of the inductive switch A is equal to that of the inductive switch B.

As a further improvement of the utility model, a protruded mounting portion A into which the magnet A is inserted and a protruded mounting portion B into which the magnet B is inserted are protruded outwards on the side edge of the conductive core respectively.

As a further improvement of the utility model, a second abdicating opening for the protruded mounting portion A and the protruded mounting portion. B to move up and down is formed on the base, and the inductive switch A and the inductive switch are provided on an outer side edge of the second abdicating opening.

As a further improvement of the utility model, the inductive switch A is one of a magnetic inductor and a Hall element, and the inductive switch B is one of the magnetic inductor and the Hall element.

As a further improvement of the utility model, the cover is covered on the base to form an accommodating cavity, a sounding elastic member is arranged in the accommodating cavity, a pressing protrusion facing the sounding elastic member is convexly arranged on the side edge of the conductive core, and a guide inclined surface is arranged on the base; in a natural state, one end of the sounding elastic member extends below the pressing protrusion and is positioned above the guide inclined surface.

As a further improvement of the utility model, the sounding elastic member is a torsion spring.

As a further improvement of the utility model, the sounding elastic member is provided on the base or the cover.

As a further improvement of the utility model, an elastic movable plate is provided on the base, and an elastic part of the elastic movable plate extends below the sounding elastic member.

The utility model has the following beneficial effects.

(1) Two conducting components are triggered to conduct in sequence by arranging two conducting components additionally in the single key switch and pressing the conductive core downwards, thereby achieving dual-conductive function of pressing once and performing two actions for a product, which gives more functions to the key switch and provides better user experience.

(2) The sounding elastic member and the elastic movable plate are additionally arranged, so that a press-sounding function is realized, with loud sound and good effect. Meanwhile, the press hand feeling is increased, and the user experience is improved.

The above mentioned is an overview of the technical scheme of the utility model. The following is a further explanation of the utility model in combination with the attached drawings and specific implementations.

### BRIEF DESCRIPTION OF THE DRAWINGS

FIG. 1 is an exploded view according to Embodiment 1;

FIG. 2 is a structurally schematic view of a conductive core according to Embodiment 1;

FIG. 3 is a structurally schematic view of a first conducting component according to Embodiment 1;

FIG. 4 is a structurally schematic view of a second conducting component according to Embodiment 1;

FIG. 5 is a diagram showing the position relationship among the conductive core, the first conducting component and the second conducting component in an initial non-pressed state;

FIG. 6 is a diagram showing the position relationship among the conductive core, the first conducting component and the second conducting component when the conductive core is pressed to a first stroke in Embodiment 1;

FIG. 7 is a diagram showing the position relationship among the conductive core, the first conducting component and the second conducting component when the conductive core is pressed to a second stroke in Embodiment 1;

FIG. 8 is a schematic view showing a structure in which the first conducting component and the second conducting component are arranged on the base according to Embodiment 1;

FIG. 9 is an overall sectional view according to Embodiment 1;

FIG. 10 is a schematic view of an external structure according to Embodiment 1;

FIG. 11 is an exploded view according to Embodiment 2;

FIG. 12 is a a schematic view of an external structure according to Embodiment 2;

FIG. 13 is a sectional view according to Embodiment 2;

FIG. 14 is a structurally schematic view of a part of Embodiment 2;

FIG. 15 is a structurally schematic view of another part of Embodiment 2;

FIG. 16 is a structurally schematic view of a base according to Embodiment 2;

FIG. 17 is an exploded view according to Embodiment 3;

FIG. 18 is a sectional view according to Embodiment 3;

FIG. 19 is a structurally schematic view of a part of Embodiment 3.

FIG. 20 is a structurally schematic view of another part of Embodiment 3.

FIG. 21 is a structurally schematic view of a base according to Embodiment 3.

FIG. 22 is a structurally schematic view of a part of Embodiment 4.

FIG. 23 is a schematic view showing a structure in which a sounding elastic member is provided on a cover according to Embodiment 4.

### DETAILED DESCRIPTION

In order to further explain the technical means and effects of the present utility model for achieving the intended purpose, the following detailed description of the embodiments of the present utility model will be made with reference to the accompanying drawings and preferred embodiments.

### Embodiment 1

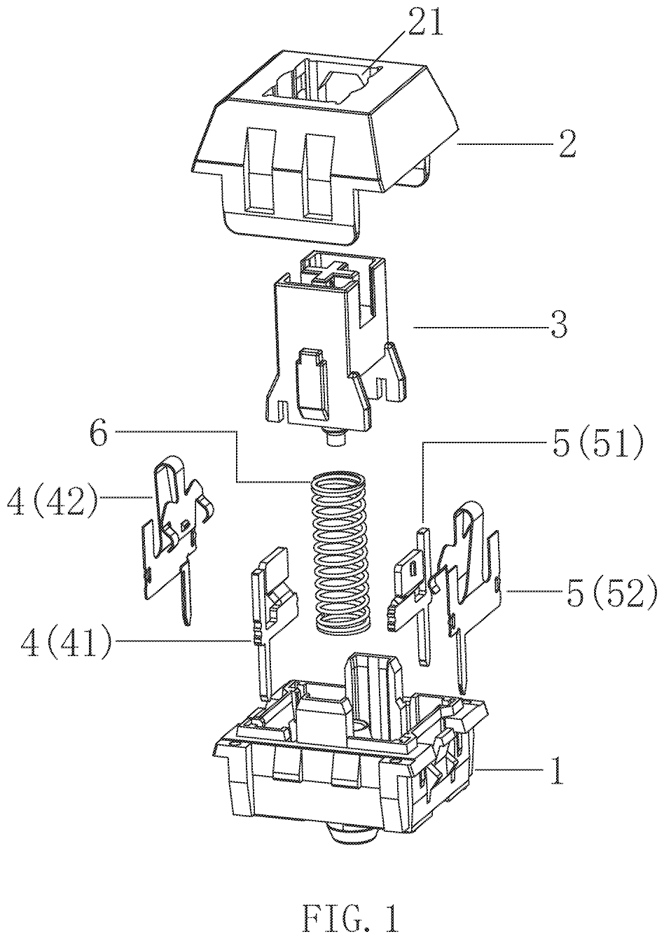

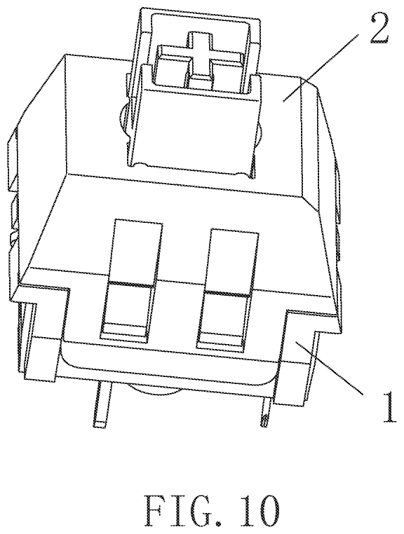

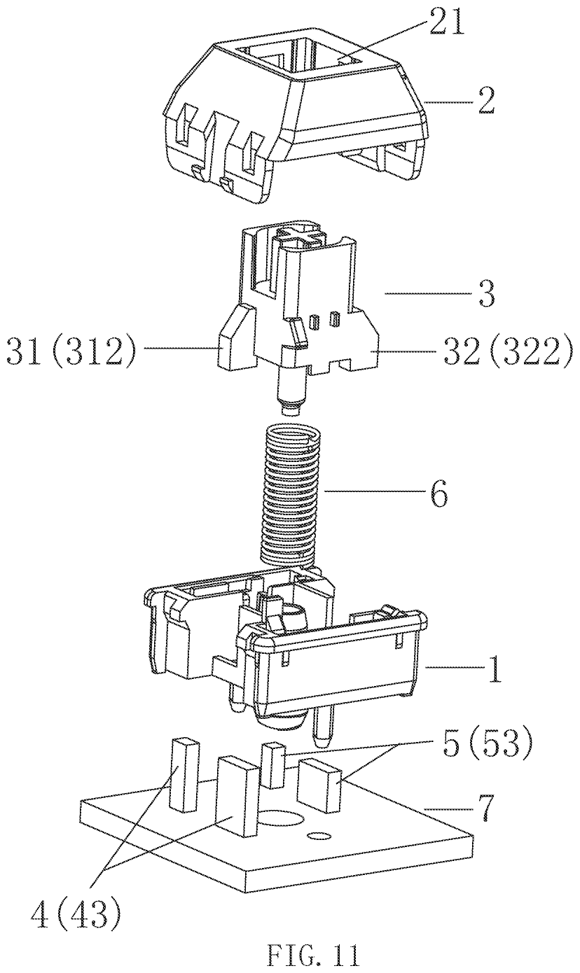

Referring to FIGS. 1 to 10, the embodiment provides a dual-conductive key switch comprising a base 1, a cover 2 arranged above the base 1, and a conductive core 3, wherein the cover 2 is covered on the base 1 to form an accommodating cavity, the conductive core 3 is arranged in the accommodating cavity, an opening 21 for allowing an upper part of the conductive core 3 to pass through is formed in the cover 2 so as to press the conductive core 3 downwards to trigger the conduction of the key switch.

According to the embodiment, the key switch further comprises a first conducting component 4 and a second conducting component 5 which are triggered to conduct sequentially by the conductive core 3. When the conductive core 3 is pressed downwards, the first conducting component 4 and the second conducting component 5 are sequentially conducted, that is, the conducting strokes of the first conducting component 4 and the second conducting component 5 which are sequentially conducted are different, so that the dual-conductive function of the key switch is realized.

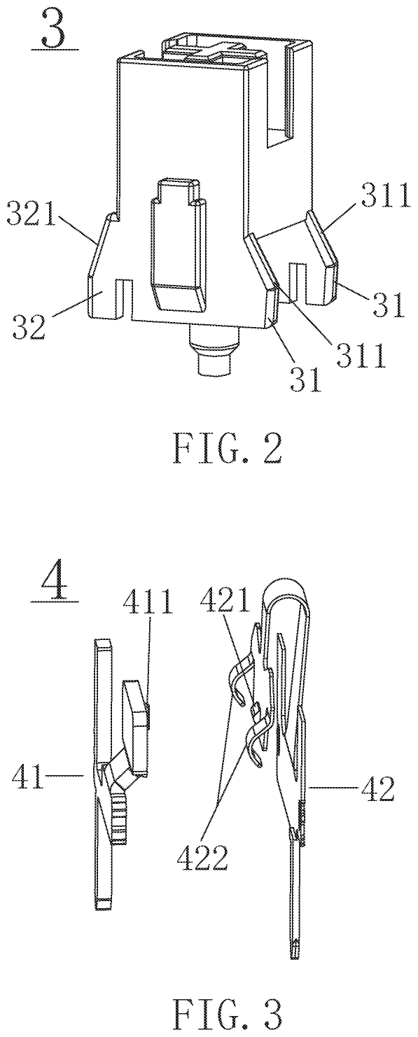

Specifically, as shown in FIG. 2, at least one first conducting trigger 31 corresponding to the first conducting component 4 and at least one second conducting trigger 32 corresponding to the second conducting component 5 are respectively arranged on the conductive core 3; and the first conducting trigger 31 triggers a conduction stroke of conducting the first conducting component 31, which is different from the conduction stroke of conducting the second conducting component 5 triggered by the second conducting trigger 32. Therefore, when the conductive core 3 is pressed downwards, the first conducting component 4 can be triggered to conduct earlier by the first conducting trigger 31, the conductive core 3 is continuously pressed, and the second conducting component 5 is triggered to conduct by the second conducting trigger 32.

Meanwhile, a first inclined surface 311 is formed on the side edge of the first conducting trigger 31, a second inclined surface 321 is formed on the side edge of the second conducting trigger 32, and the slope of the first inclined surface 311 is greater than that of the second inclined surface 321. Since the slopes of the first inclined surface 311 and the second inclined plane 321 are different, the first conducting component 4 and the second conducting component 5 can be conducted sequentially when the first conducting trigger 31 and the second conducting trigger 32 move down with the conductive core 3. In the embodiment, the first conducting component 4 and the second conducting component 5 are both conduction structures of a movable plate and a stationary plate, and the specific structure is as follows.

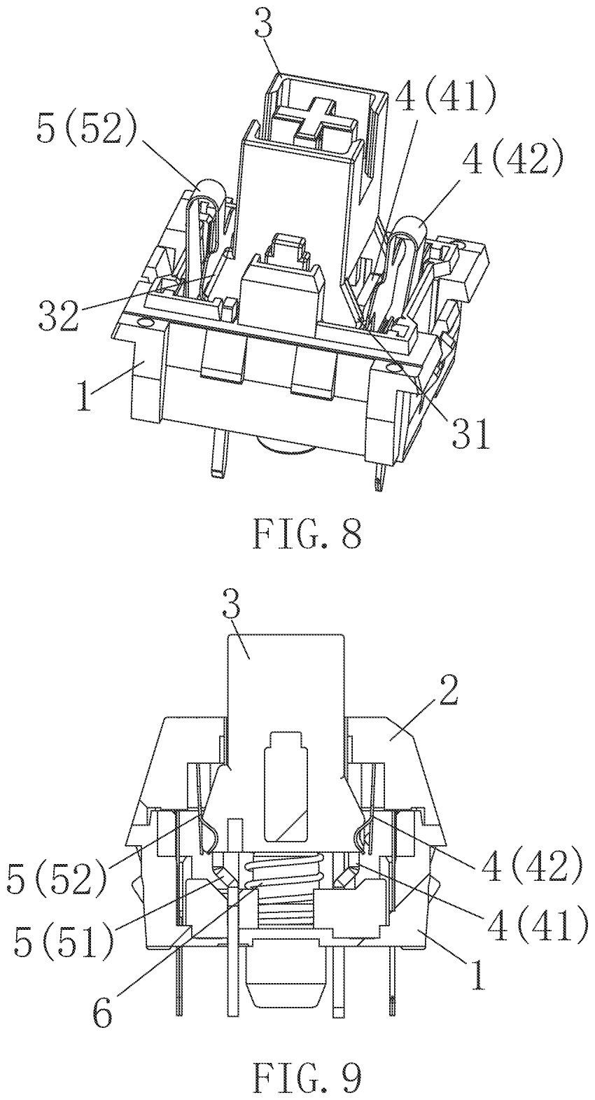

As shown in FIG. 3, the first conducting component 4 comprises a first stationary plate 41 and a first movable plate 42, wherein a first stationary contact 411 is provided on the first stationary plate 41, a first movable contact 421 corresponding to the first stationary contact 411 is provided on the first movable plate 42, and at least one first contact protrusion 422 corresponding to the first conducting trigger 31 is formed on the first movable plate 42. Specifically, the number of the first contact protrusion 422 and the first conducting trigger 31 may be set to be two respectively and one-to-one. As for the mounting of the first stationary plate 41 and the first movable plate 42, the first stationary plate 41 and the first movable plate 42 can be mounted on the base 1 and positioned on the outer side of the first conducting trigger 31 on the conductive core 3. Specifically, the first stationary plate 41 is positioned in the inner side, and the first movable plate 42 is positioned outside, as shown in FIG. 8. Meanwhile, the lower ends of the first stationary plate 41 and the first movable plate 42 pass through the lower end face of the base 1 and are electrically connected with the PCB. During the upward and downward movement of the conductive core 3, the first conducting component 4 is not longitudinally displaced.

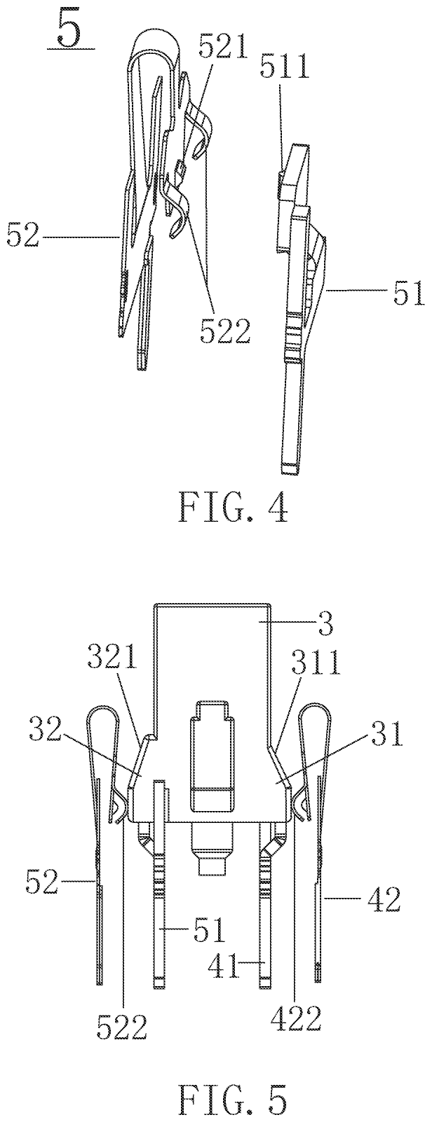

Specifically, as shown in FIG. 4, the second conducting component 5 comprises a second stationary plate 51 and a second movable plate 52, a second stationary contact 511 is provided on the second stationary plate 51, a second movable contact 521 corresponding to the second stationary contact 511 is provided on the second movable plate 52, and at least one second contact protrusion 522 corresponding to the second conducting trigger 32 is formed on the second movable plate 52. Specifically, the number of the second contact protrusion 522 and the second conducting trigger 32 may be set to be two respectively and one-to-one. As for the mounting of the second stationary plate 51 and the second movable plate 52, the second stationary plate 51 and the second movable plate 52 can be mounted on the base 1 and positioned on the outer side of the second conducting trigger 32 on the conductive core 3. Specifically, the second stationary plate 51 is positioned on the inner side, and the second movable plate 52 is positioned on the outer side, as shown in FIGS. 8 and 9. Meanwhile, the lower ends of the second stationary plate 51 and the second movable plate 52 pass through the lower end face of the base 1 and are electrically connected with the PCB. During the upward and downward movement of the conductive core 3, the second conducting component 5 is not longitudinally displaced.

In this embodiment, both the first movable plate 42 and the second movable plate 52 are made of a material having a certain elasticity, such as stainless steel or the like.

In the initial non-pressed state, as shown in FIG. 5, when the first conducting trigger 31 pushes outward against the first contact protrusion 422 on the first movable plate 42, the upper portion of the first movable plate 42 is bent outward to deform, so that the first movable contact 421 is separated from the first stationary contact 411, that is, the first conducting component 4 is in a non-conductive state. At the same time, when the second conducting trigger 32 pushes outwardly against the second contact protrusion 522 on the second movable plate 52, the upper portion of the second movable plate 52 is bent outwardly to deform, so that the second movable contact 521 is separated from the second stationary contact 511, i.e. the second conducting component 5 is in a non-conductive state.

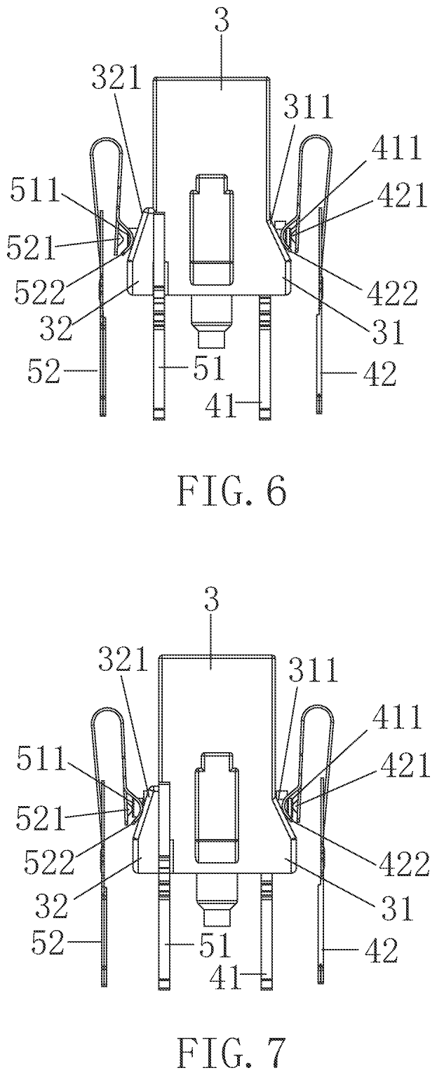

When the conductive core 3 is pressed downwards, as shown in FIG. 6, the conductive core 3 is continuously moved downwards. When the conductive core 3 is moved downwards to the first contact protrusion 422 and comes into contact with the first inclined surface 311 on the first conducting trigger 31, the upper portion of the first movable plate 42 rebounds inward under the guiding action of the first inclined surface 311 until the first movable contact 421 comes into contact with the first stationary contact 411, so that the first conducting component 4 is conducted. In this process, the second contact protrusion 522 is in contact with the second inclined surface 321 on the second conducting trigger 32; and the upper portion of the second movable plate 52 rebounds inward under the guiding action of the second inclined surface 321. However, since the slope of the first inclined surface 311 is greater than that of the second inclined surface 321, it is inevitable that the first movable contact 421 is in contact conduction with the first stationary contact 411 first. When the first conducting component 4 is just conductive, the second movable contact 521 is not yet in contact with the second stationary contact 511. That is, the first conducting component 4 is conductive and the second conducting component 5 is non-conductive during the first stroke in which the core 3 moves downward.

With continuing to press the conductive core 3 downwards, as shown in FIG. 7, the conductive core 3 continues to move downwards; under the guiding effect of the first inclined surface 311, the upper part of the first movable plate 42 continues to rebound inwards, the first movable contact 421 is always, in contact with the first stationary contact 411, and the first conducting component 4 is always conducted. In this process, under the guidance of the second inclined surface 321, the upper portion of the second movable plate 52 continues to rebound back inwardly until the second movable contact 521 contacts the second stationary contact 511 and the second conducting component 5 is conductive. That is, during the second stroke in which the conductive core 3 moves downward, the first conducting component 4 is always conductive, and the second conducting component 5 starts to conduct. Thereby, the sequential conduction of the first conducting component 4 and the second conducting component 5 is achieved.

During the above-described downward pressing of the conductive core 3, a spring 6 provided between, the conductive core 3 and the base 1 is compressed.

When the pressing of the conductive core 3 is released, the conductive core 3 moves upwards and resets under the elastic restoring force of the spring 6. Since the slope of the first inclined surface 311 is greater than that of the second inclined surface 321, the second conducting component 5 is firstly disconnected, the first conducting component 4 is then disconnected, and the initial non-pressed state is restored.

### Embodiment 2

The main difference between this embodiment and Embodiment 1 is as follows. Referring to FIGS. 11 to 14, the first conducting component 4 is a light-conducting component A 43 electrically connected to a PCB 7, and the second conducting component 5 is a light-conducting component B 53 electrically connected to the PCB 7; the first conducting trigger 31 is a light-blocking protrusion A 312, and the second conducting trigger 32 is a light-blocking protrusion B 322; and the distance between the light-blocking protrusion A 312 and the light-conducting component A 43 is less than the distance between the light-blocking protrusion B 322 and the light-conducting component B 53. When the conductive core 3 is pressed to move downwards, the light-blocking protrusion A 312 and the light-blocking protrusion B 322 move downwards. Since the distance between the light-blocking protrusion A 312 and the light-conducting component A 43 is less than the distance between the light-blocking protrusion B 322 and the light-conducting component B 53, the light-blocking protrusion A 312 reaches the light-conducting component. A 43 firstly and blocks the light path of the light-conducting component A 43; and the light-blocking protrusion B 322 reaches the light-conducting component B 53 and blocks the light path of the light-conducting component B 53. Therefore, compared with the light-conducting component B 53, the light-conducting component A 43 firstly generates a signal that the light path is blocked, namely the light-conducting component A 43 is conducted earlier, and the light-conducting component B 53 is conducted later, thereby achieving the purpose of conducting in sequence. According to the embodiment, the dual-conductive function of the key switch is realized by different conduction strokes of conduction in sequence.

For the distance between the light-blocking protrusion A 312 and the light-conducting component A 43, which is less than the distance between the light-blocking protrusion B 322 and the light-conducting component B 53, the following two methods can be adopted.

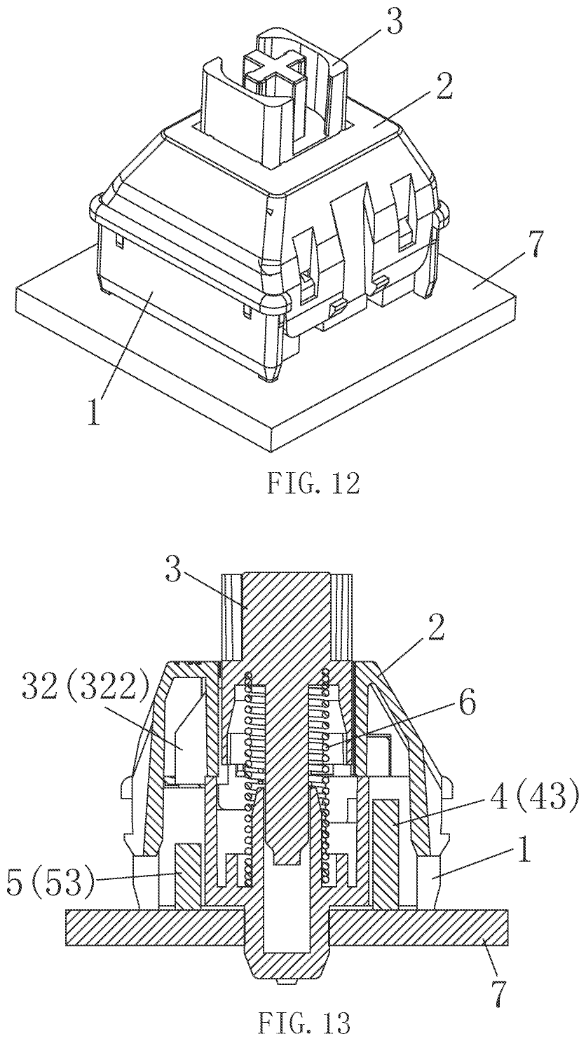

(1) The height of the light-blocking protrusion A 312 is the same as that of the light-blocking protrusion B 322, and the height of the light-conducting component A 43 is higher than that of the light-conducting component B 53, as shown in FIGS. 13 to 16. When the conductive core 3 is pressed to move downwards, the light-blocking protrusion A 312 and the light-blocking protrusion B 322 move downwards, and the heights of the light-blocking protrusion A 312 and the light-blocking protrusion B 322 are always the same in the process of moving downwards. Since the height of the light-conducting component A 43 is higher than that of the light-conducting component B 53, the light-blocking protrusion A 312 reaches the light-conducting component A 43 earlier and blocks the light path of the light-conducting component A 43, and the light-blocking protrusion B 322 reaches the light-conducting component B 53 later and blocks the light path of the light-conducting component B 53. Therefore, compared with the light-conducting component B 53, the light-conducting component A 43 firstly generates a signal that the light path is blocked, namely the light-conducting component A 43 is conducted earlier, and the light-conducting component B 53 is conducted later, thereby achieving the purpose of conducting in sequence.

(2) The height of the light-blocking protrusion A 312 is lower than that of the light-blocking protrusion B 322, and the height of the light-conducting component A 43 is the same as that of the light-conducting component B 53. In the specific structural design, it works as long as the position height of the light-blocking protrusion A 312 on the conductive core 3 is designed to be lower than the position height of the light-blocking protrusion B 322 on the conductive core 3. When the conductive core 3 is pressed to move downwards, the light-blocking protrusion A 312 and the light-blocking protrusion B 322 move downwards synchronously along with the conductive core 3, and the position height of the light-blocking protrusion A 312 is always lower than that of the light-blocking protrusion B 322 during the downwards moving process. Since the height of the light-conducting component A 43 is equal to the height of the light-conducting component B 53, the light-blocking protrusion A 312 reaches the light-conducting component A 43 earlier and blocks the light path of the light-conducting component A 43, and the light-blocking protrusion B 322 reaches the light-conducting component B 53 later and blocks the light path of the light-conducting component B 53. Therefore, compared with the light-conducting component B 53, the light-conducting component A 43 firstly generates a signal that the light path is blocked, namely the light-conducting component A 43 is conducted earlier, and the light-conducting component B 53 is conducted later, thereby achieving the purpose of conducting in sequence.

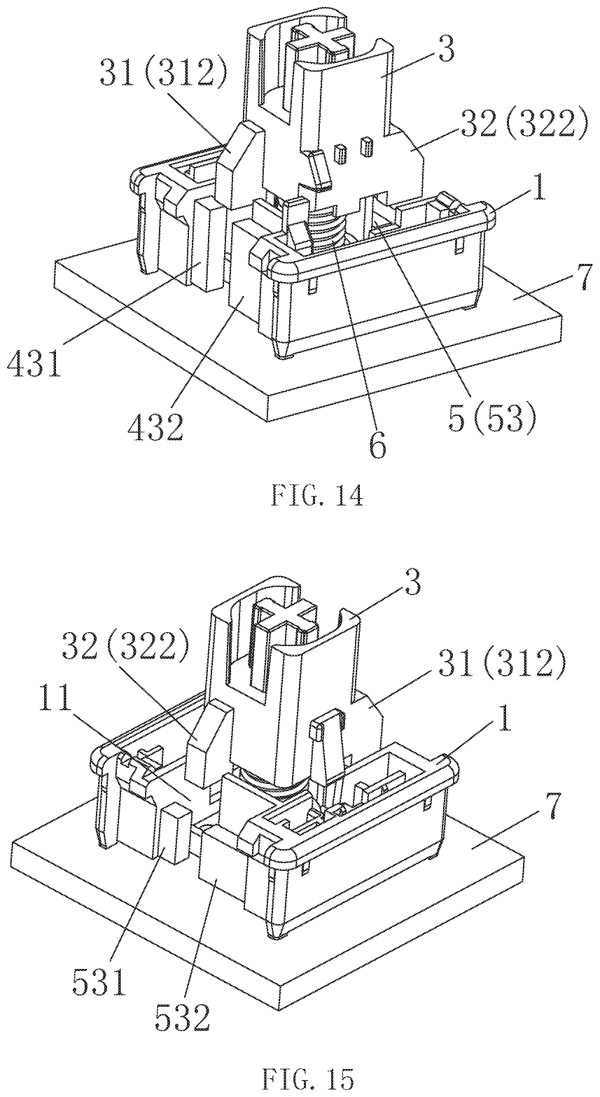

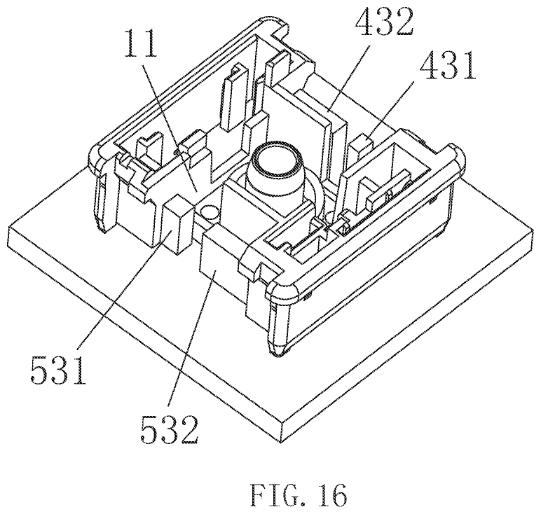

In order to facilitate the upward and downward movement of the light-blocking protrusion A 322 and the light-blocking protrusion B 322, a first abdicating opening 11 for the light-blocking protrusion A 322 and the light-blocking protrusion B 322 to move up and down is formed on the base 1 in the present embodiment, as shown in FIGS. 15 and 16.

In the present embodiment, the light-conducting component A 43 has the same structure as the light-conducting component B 53, and includes a light emission element (431, 531) and a light reception element (432, 532), respectively. In the case where there is no structural interruption between the light emission element (431, 531) and the light reception element (432, 532) the light emission element (431, 531) emits a light signal, and the light reception element (432, 532) receives a light signal. When the structural interruption occurs between the light emission element (431, 531) and the light reception element (432, 532), the light reception element (432, 532) cannot receive the light signal emitted by the light emission element (431, 531), i.e., a signal in which the optical path is blocked occurs.

The key switch adopting the light-conducting component is an optical axis key switch. The working principle is as follows.

In a natural state, the light-blocking protrusion arranged on the conductive core 3 does not reach the light-conducting component, and the light reception element in the light-conducting component can normally receive the light signal emitted by the light emission element and can be preset through a circuit on the PCB 7, in which case the key switch is in an off state.

When the conductive core 3 is pressed downwards, the conductive core 3 drives the light-blocking protrusion to move downwards synchronously until the light-blocking protrusion extends between the light emission element and the light reception element to block an optical path between the light emission element and the light reception element, so that the light reception element cannot receive a light signal emitted by the light emission element, i.e. a signal that the optical path is blocked is generated, and the key switch is set to be conducted.

When the pressing of the conductive core 3 is released, the conductive core 3 moves upwards and resets under the elastic restoring force of a spring 6 to drive the light-blocking protrusion to move upwards. When the light-blocking protrusion leaves from between the light emission element and the light reception element, the light reception element receives the light signal emitted by the light emission element again, and the key switch returns to an off state.

In this embodiment, since the distance between the light-blocking protrusion A 312 and the light-conducting component A 43 is less than the distance between the light-blocking protrusion B 322 and the light-conducting component B 53, and when the conductive core 3 is pressed downward, the light-blocking protrusion A 312 first protrudes between the light emission element 431 and the light reception element 432, and blocks an optical signal emitted to the light reception element 432 from the light emission element 431, and the light-blocking protrusion B 322 blocks an optical signal emitted to the light reception element 532 from the light emission element 531. That is, the light-conducting component A 43 generates a signal that the optical path is blocked before the light-conducting component B 53, i.e. the light-conducting component A 43 is conducted earlier, and the light-conducting component B 53 is conducted, thereby achieving the purpose of conducting in sequence.

When the pressing of the conductive core 3 is released and the conductive core 3 moves upwards and resets, and the light-blocking protrusion B 322 leaves the light-conducting component B 53 earlier, the signal that the light path generated by the light-conducting component B 53 is blocked disappears, and the signal that the light path generated by the light-conducting component A 43 is blocked disappears later, namely the light-conducting component B 53 is disconnected before the light-conducting component A 43.

### Embodiment 3

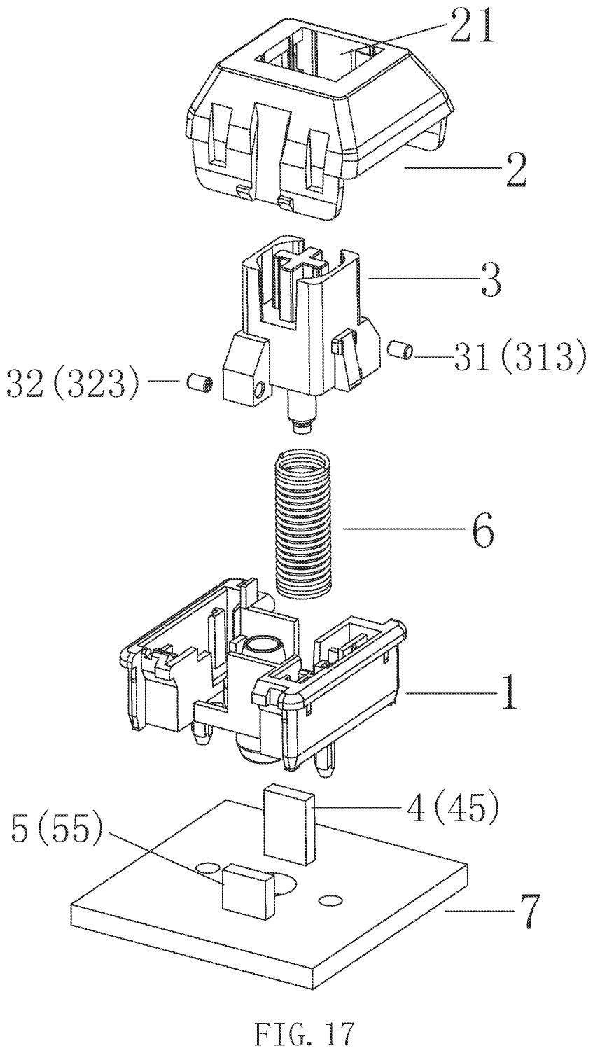

The main difference between this embodiment and Embodiment 1 is as follows. Referring to FIGS. 17 to 20, the first conducting component 4 is an inductive switch A 45 electrically connected to a PCB 7, the second conducting component 5 is an inductive switch B 55 electrically connected to the PCB 7, the first conductive trigger 31 is a magnet A 313, the second conductive trigger 32 is a magnet B 323, and the distance between the magnet A 313 and the inductive switch A 45 is less than the distance between magnet B 323 and inductive switch B 55. When the conductive core 3 is pressed to move downwards, the magnet A 313 and the magnet B 323 move downwards. Since the distance between the magnet A 313 and the inductive switch A 45 is less than the distance between the magnet B 323 and the inductive switch B 55, the inductive switch A 45 firstly inducts the magnetism of the magnet A 313, and the inductive switch B 55 then inducts the magnetism of the magnet B 323. That is, the first conducting component 4 is conducted earlier, and the second conducting component 5 is conducted later, thereby achieving the purpose of conducting the first conducting component 4 and the second conducting component 5 sequentially. Therefore, the dual-conduction function of the key switch is realized by different conduction strokes of the first conducting component 4 and the second conducting component 5 which are sequentially conducted.

For the distance between the magnet A 313 and the inductive switch A 45, which is less than the distance between the magnet B 323 and the inductive switch B 55, the following two modes can be adopted.

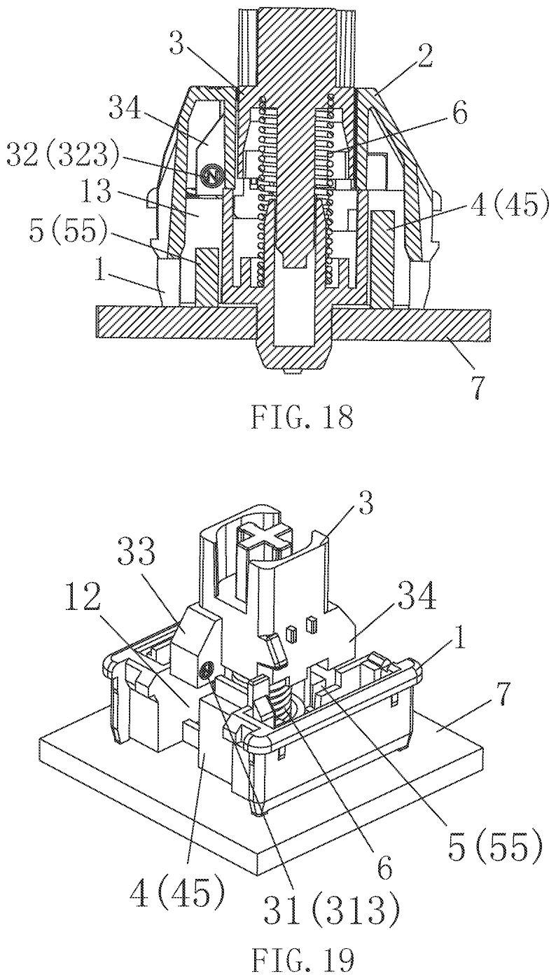

(1) The height of the magnet A 313 is the same as that of the magnet B 323, and the height of the inductive switch A 45 is higher than that of the inductive switch B 55, as shown in FIGS. 18 to 21. When the conductive core 3 is pressed to move downwards, the magnet A 313 and the magnet B 323 move downwards synchronously along with the conductive core 3, and the heights of the magnet A 313 and the magnet B 323 are always the same in the process of moving downwards. Since the height of the inductive switch A 45 is higher than that of the inductive switch B 55, the magnet A 313 approaches to the inductive switch A 45 before the magnet B 323, the inductive switch A 45 firstly inducts the magnetism of the magnet A 313, and the inductive switch B 55 inducts the magnetism of the magnet B 323 later, thereby achieving the purposes of conducting the first conducting component 4 earlier and conducting the second conducting component 5 later.

(2) The height of the magnet A 313 is lower than that of the magnet B 323, and the height of the inductive switch A 45 is equal to that of the inductive switch B 55. In the specific structural design, as long as the position height of the magnet A 313 on the conductive core 3 is designed to be lower than the position height of the magnet B 323 on the conductive core 3. When the conductive core 3 is pressed to move downwards, the magnet A 313 and the magnet B 323 move downwards synchronously along with the conductive core 3, and the position height of the magnet A 313 is always lower than that of the magnet B 323 in the downwards moving process. Since the height of the inductive switch A 45 is equal to the height of the inductive switch B 55 the magnet A 313 approaches to the inductive switch A 45 before the magnet B 323, the inductive switch A 45 firstly inducts the magnetism of the magnet A 313, and the inductive switch B 55 inducts the magnetism of the magnet B 323 later, thereby achieving the purposes of conducting the first conducting component 4 earlier and conducting the second conducting component 5 later.

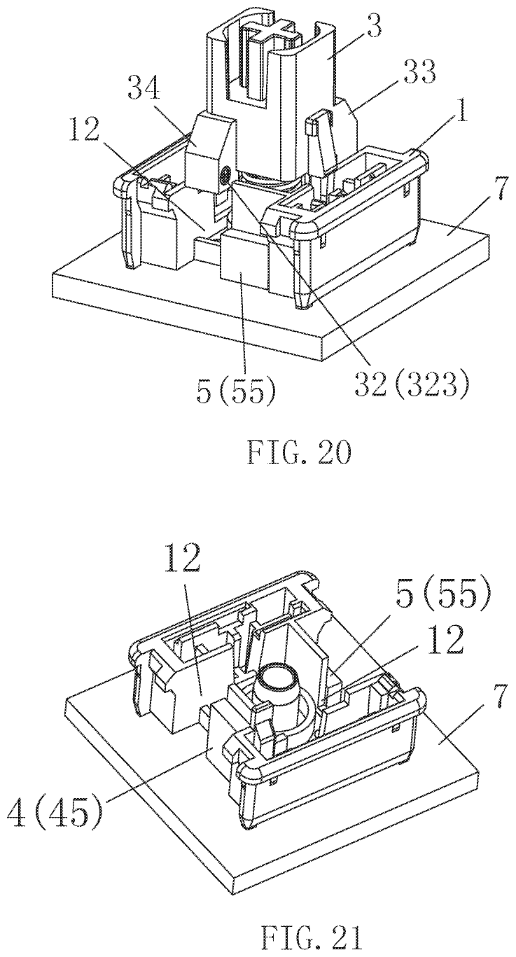

With regard to the mounting manner of the magnet A 313 and the magnet B 323 on the conductive core 3, as shown in FIGS. 19 and 20, a protruding mounting portion A 33 into which the magnet A 313 is inserted and a protruding mounting portion B 34 into which the magnet B 323 is inserted are protruded outwardly on the side edge of the conductive core 3 respectively. When the protruded mounting portion A 33 and the protruded mounting portion B 34 move up and down along with the conductive core 3 as a whole, the magnet A 313 and the magnet B 323 move up and down along with synchronization so as to achieve the purpose of sequential dual conduction.

In order to facilitate the protruded mounting portion A 33 to drive the magnet A 313 and the protruded mounting portion B 34 to drive the magnet B 323 to move up and down, a second abdicating opening 12 for the protruded mounting portion A 33 and the protruded mounting portion B 34 to move up and down is respectively formed on the base 1, and the inductive switch A 45 and the inductive switch B 55 are arranged on the outer side edge of the second abdicating opening 12 as shown in FIG. 21. When the protruded mounting portion A 33 drives the magnet A 313 and the protruded mounting portion B 34 drives the magnet B 323 to move up and down, the magnetism of the magnet A 313 is induced by the inductive switch A 45 on, the side edge of the second abdicating opening 12, and the magnetism of the magnet B 323 is induced by the inductive switch B 55 so that the purpose of sequential dual conduction is achieved.

In the embodiment, the inductive switch A 45 is one of a magnetic inductor and a Hall element. When the inductive switch A 45 is a magnetic inductor, the magnet A 313 and the inductive switch A 45 are combined to form the magnetic inductive switch. When the inductive switch A 45 is a Hall element, the magnet A 313 and the inductive switch A 45 are combined to form a Hall inductive switch. Similarly, the inductive switch B 55 is one of a magnetic inductor and a Hall element. When the inductive switch B 55 is a magnetic inductor, the magnet B 323 and the inductive switch B 55 are combined to form a magnetic inductive switch. When the inductive switch B 55 is a Hall element, the magnet B 323 and the inductive switch B 55 are combined to form a Hall inductive switch.

Specifically, the working principle of the magnetic inductive switch is as follows.

In a natural state, when the distance between the magnet on the conductive core 3 and the magnetic inductor on the PCB 7 is far enough, the magnetic inductor on the PCB 7 cannot induct the magnetism of the magnet on the conductive core 3, and the circuit is disconnected, that is, the key switch is in an off state.

When the conductive core 3 is pressed downwards, the conductive core 3 drives the magnet to act downwards. When the conductive core 3 is pressed downwards to a certain stroke, and it reaches a certain distance between the magnet and the magnetic inductor on the PCB 7, the magnetic inductor inducts the magnetism, and the circuit is conducted, that is, the key switch is in an on state.

When the pressing of the conductive core 3 is released, the conductive core 3 moves upwards and resets under the elastic restoring force of the spring 6 to drive the magnet to move upwards. When the distance between the magnet and the magnetic inductor is far enough, the magnetic inductor on the PCB 7 cannot induct the magnetism of the magnet, the circuit is disconnected, and the magnetic inductive switch returns to the off state.

In the embodiment, since the distance between the magnet A 313 and the inductive switch A 45 is less than the distance between the magnet B 323 and the inductive switch B 55, and when the conductive core 3 is pressed downwards, the magnet A 313 approaches to the inductive switch A 45 firstly, the first conducting component 4 is conducted earlier, and the second conducting component 5 is conducted later, thereby achieving the purpose of conducting in sequence. When the pressing of the conductive core 3 is released and the conductive core 3 moves upwards and resets, the magnet B 323 is firstly far away from the inductive switch B 55, the second conducting component 5 is disconnected earlier, and the first conducting component 4 is disconnected later. Specifically, the working principle of the Hall inductive switch is as follows.

In a natural state, when the distance between the magnet 7 on the conductive core 3 and the Hall element on the PCB 7 is far enough, and the Hall element on the PCB 7 cannot induct the magnetism of the magnet 7 on the conductive core 3, that is, no signal is generated by the Hall element; and the circuit is disconnected, that is, the key switch is in an off state.

When the conductive core 3 is pressed downwards, the conductive core 3 drives the magnet 7 to move downwards. When the conductive core 3 is pressed downwards to a certain stroke, and it reaches a certain distance between the magnet and the magnetic inductor on the PCB 7, the Hall element inducts the magnetism, that is, the Hall element generates a signal (for example, a signal of changing a resistance value, a signal of changing the voltage value and the like). Along with the increase of the magnetic force, the signal value is also increased along therewith, and linearly increased, and the electrical property is output, the circuit is conducted, namely the key switch is in an on state.

When the pressing of the conductive core 3 is released, the conductive core 3 moves upwards and resets under the action of the elastic restoring force of the spring 6 to drive the magnet to move upwards. When the distance between the magnet and the Hall element is far enough, the Hall element on the PCB 7 cannot conduct the magnetism of the magnet 7, that is, no signal, is generated by the Hall element, the circuit is disconnected, and the key switch returns to the off state.

In the embodiment, since the distance between the magnet A 313 and the inductive switch A 45 is less than the distance between the magnet B 323 and the inductive switch B 55, and when the conductive core 3 is pressed downwards, the magnet A 313 approaches to the inductive switch A 45 firstly, the first conducting component 4 is conducted earlier, and the second conducting component 5 is conducted later, thereby achieving the purpose of conducting in sequence. When the pressing of the conductive core 3 is released and the conductive core 3 moves upwards and resets, the magnet B 323 is firstly far away from the inductive switch B 55, the second conducting component 5 is disconnected earlier, and the first conducting component 4 is disconnected later.

### Embodiment 4

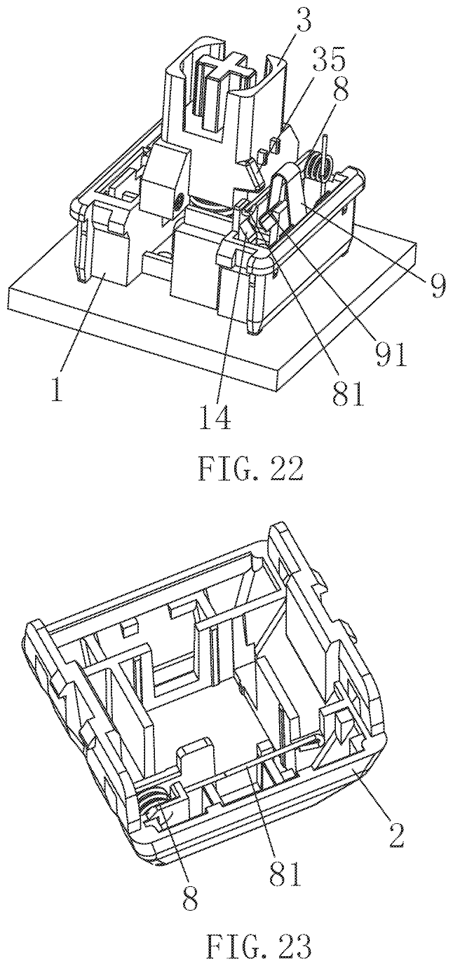

The main difference between this embodiment and any one of Embodiments 1 to 3 is as follows. As shown in FIGS. 22 and 23, the cover 2 is covered on the base 1 to form an accommodating cavity 13, a sounding elastic member 8 is arranged in the accommodating cavity 13, a pressing protrusion 35 facing the sounding elastic member 8 is convexly arranged on the side edge of the conductive core 3, and a guide inclined surface 14 is arranged on the base. In a natural state, one end 81 of the sounding elastic member 8 extends below the pressing protrusion 35 and is located above the guide inclined surface 14. Specifically, the sounding elastic member 8 is a torsion spring, and specifically, the torsion spring is made of a stainless steel material, namely a stainless steel torsion spring.

With regard to the specific mounting of the sounding elastic member 8, the sounding elastic member 8 in this embodiment is provided on the base 1 or the cover 2. Specifically, as shown in FIG. 23, the main body portion of the torsion spring is limited to the cover 2, but it is also possible to limit the main body portion of the torsion spring to the base 1.

When the conductive core 3 is pressed downwards, the pressing protrusion 35 is driven to move downwards, and the pressing protrusion 35 presses one end 81 of the sounding elastic member 8 (torsion spring) downwards. When it is pressed down to a certain position, the guide inclined surface 14 on the base 1 guides one end 81 of the sounding elastic member 8 to escape from the pressing protrusion 35, and one end 81 of the sounding elastic member 8 releases the potential energy and bounces to knock the base 1, the cover 2 and/or the pressing protrusion 35 and make a sound, so that a press-sounding function is realized, with loud sound and good effect.

Meanwhile, in order to further improve the pressing feel, the present embodiment is provided with an elastic movable plate 9 on the base 1, and the elastic movable plate 9 has an elastic elastic part 91 extending below the sounding elastic member 8. When the conductive core 3 is pressed downwards to drive the pressing protrusion 35 to move downwards, one end 81 of the sounding elastic member 8 is pressed downwards by the pressing protrusion 35. When one end 81 of the sounding elastic member 8 is pressed downwards, the sounding elastic member 8 acts on the elastic moving piece 9 which is deformed, so that the press hand feeling is improved.

In the description above, only the preferred embodiments of the utility model has been described, and the technical scope of the utility model is not limited in any way. Therefore, other structures obtained by adopting the same or similar technical features as those of the above embodiments of the utility model are within the scope of the utility model.

1. A dual-conductive key switch comprising a base, a cover arranged above the base, and a conductive core, wherein it further comprises a first conducting component and a second conducting component which are triggered to conduct sequentially by the conductive core.

2. The dual-conductive key switch according to claim 1, wherein at least one first conducting trigger corresponding to the first conducting component and at least one second conducting, trigger corresponding to the second conducting component are respectively arranged on the conductive core; and the first conducting trigger triggers a conduction stroke of conducting the first conducting component, which is different from a conduction stroke of conducting the second conducting component triggered by the second conducting trigger.

3. The dual-conductive key switch according to claim 2, wherein a first inclined surface is formed on the side edge of the first conducting trigger, a second inclined surface is formed on the side edge of the second conducting trigger, and the slope of the first inclined surface is greater than that of the second inclined surface.

4. The dual-conductive key switch according to claim 2, wherein the first conducting component comprises a first stationary plate and a first movable plate, a first stationary contact is arranged on the first stationary plate, a first movable contact corresponding to the first stationary contact is arranged on the first movable plate, and at least one first contact protrusion corresponding to the first conducting trigger is formed on the first movable plate; and the second conducting component comprises a second stationary plate and a second movable plate, a second stationary contact is arranged on the second stationary plate, a second movable contact corresponding to the second stationary contact is arranged on the second movable plate, and at least one second contact protrusion corresponding to the second conducting trigger is formed on the second movable plate.

5. The dual-conductive key switch according to claim 2, wherein the first conducting component is a light-conducting component A electrically connected to a PCB, and the second conducting component is a light-conducting component B electrically connected to the PCB; the first conducting trigger is a light-blocking protrusion A, and the second conducting trigger is a light-blocking protrusion B, and the distance between the light-blocking protrusion A and the light-conducting component A is less than the distance between the light-blocking protrusion B and the light-conducting component B.

6. The dual-conductive key switch according to claim 5, wherein the height of the light-blocking protrusion A is the same as that of the light-blocking protrusion B, and the height of the light-conducting component A is higher than that of the light-conducting component B.

7. The dual-conductive key switch according to claim 5, wherein the height of the light-blocking protrusion A is lower than that of the light-blocking protrusion B, and the height of the light-conducting component A is the same as that of the light-conducting component B.

8. The dual-conductive key switch according to claim 5, wherein a first abdicating opening for the light-blocking protrusion A and the light-blocking protrusion B to move up and down is formed on the base.

9. The dual-conductive key switch according to claim 5, wherein the light-conducting component A and the light-conducting component B have a same structure and comprise a light emission element and a light reception element respectively.

10. The dual-conductive key switch according to claim 2, wherein the first conducting component is an inductive switch A electrically connected to the PCB, and the second conducting component is an inductive switch B electrically connected to the PCB; the first conducting trigger is a magnet A, and the second conducting trigger is a magnet B; and the distance between the magnet A and the inductive switch A is less than the distance between the magnet B and the inductive switch B.

11. The dual-conductive key switch according to claim 10, wherein the height of the magnet A is the same as that of the magnet B, and the height of the inductive switch A is higher than that of the inductive switch B.

12. The dual-conductive key switch according to claim 10, wherein the height of the magnet A is lower than that of the magnet B, and the height of the inductive switch A is equal to that of the inductive switch B.

13. The dual-conductive key switch according to claim 10, wherein a protruded mounting portion A into which the magnet A is inserted and a protruded mounting portion B into which the magnet B is inserted are protruded outwards on the side edge of the conductive core respectively.

14. The dual-conductive key switch according to claim 13, wherein a second abdicating opening for the protruded mounting portion A and the protruded mounting portion B to move up and down is formed on the base, and the inductive switch A and the inductive switch B are provided on an outer side edge of the second abdicating opening.

15. The dual-conductive key switch according to claim 10, wherein the inductive switch A is one of a magnetic inductor and a Hall element, and the inductive switch B is one of a magnetic inductor and a Hall element.

16. The dual-conductive key switch according to claim 1, wherein the cover is covered on the base to form an accommodating cavity, a sounding elastic member is arranged in the accommodating cavity, a pressing protrusion facing the sounding elastic member is convexly arranged on the side edge of the conductive core, and a guide inclined surface is arranged on the base; in a natural state, one end of the sounding elastic member extends below the pressing protrusion and is positioned above the guide inclined surface.

17. The dual-conductive key switch according to claim 16, wherein the sounding elastic member is a torsion spring.

18. The dual-conductive key switch according to claim 16, wherein the sounding elastic member is provided on the base or the cover.

19. The dual-conductive key switch according to claim 16, wherein an elastic movable plate is provided on the base, and an elastic part of the elastic movable plate extends below the sounding elastic member.
